(19) United States
(12) Patent Application Publication
(10) Pub. No.: US 2026/0354068 A1
(43) Pub. Date: Nov. 5, 2026

(54) SUBSTRATE PROCESSING METHOD AND SUBSTRATE PROCESSING APPARATUS

(71) Applicant: Tokyo Electron Limited, Tokyo (JP)

(72) Inventors: Ryo IGOSAWA, Miyagi (JP); Takahiro YONEZAWA, Miyagi (JP)

(73) Assignee: Tokyo Electron Limited, Tokyo (JP)

(21) Appl. No.: 19/720,906

(22) Filed: Jun. 26, 2026

Related U.S. Application Data
(63) Continuation of application No. PCT/JP2024/042620, filed on Dec. 3, 2024.

(30) Foreign Application Priority Data
Jan. 9, 2024 (JP) 2024-001302

(51) Int. Cl. H10P 50/00; H01J 37/32; H10P 50/24; H10P 50/26; H10P 50/28; H10P 72/00

(52) U.S. Cl. CPC H10P 50/695; H01J 37/32449; H10P 50/692; H10P 50/71; H10P 50/73; H10P 72/0421; H01J 2237/3347; H10P 50/242; H10P 50/267; H10P 50/283

(57) ABSTRACT

Provided is a technique for controlling film formation performed on a surface of a recess of an etching target film. A substrate processing method includes (a) providing a substrate including an etching target film having a recess on a substrate support in a chamber; (b) exposing the substrate to a first processing gas containing a first halogen and hydrogen to form a first layer on a surface of the recess, the first layer including at least one of a halogenated surface and a surface on which hydrogen halide is adsorbed; and (c) exposing the substrate to a plasma generated from a second processing gas containing a second halogen and a Group 14 element to form a second layer containing the second halogen and the Group 14 element on the surface of the recess.

### CROSS-REFERENCE TO RELATED APPLICATIONS

This application is a bypass continuation application of international application No. PCT/JP2024/042620 having an international filing date of Dec. 3, 2024 and designating the United States, the international application being based upon and claiming the benefit of priority from Japanese Patent Application No. 2024-001302, filed on Jan. 9, 2024, the entire contents of each are incorporated herein by reference.

### BACKGROUND

Exemplary embodiments of the present disclosure relate to a substrate processing method and a substrate processing apparatus.

Patent Literature 1 discloses a technique for forming a carbon film on a surface of a recess of an etching target film.
Patent Document 1: Japanese Patent Application Laid-Open No. 2016-21546

### SUMMARY OF INVENTION

### Summary

A substrate processing method in one exemplary embodiment of the present disclosure includes: providing a substrate including an etching target film having a recess on a substrate support in a chamber; exposing the substrate to a first processing gas containing a first halogen and hydrogen to form a first layer on a surface of the recess, the first layer including at least one of a halogenated surface and a surface on which hydrogen halide is adsorbed; and exposing the substrate to a plasma generated from a second processing gas containing a second halogen and a Group 14 element to form a second layer containing the second halogen and the Group 14 element on the surface of the recess.

### BRIEF DESCRIPTION OF DRAWINGS

FIG. 1 is a diagram for describing a configuration example of a plasma processing system.

FIG. 2 is a diagram for describing a configuration example of an inductively coupled plasma processing apparatus.

FIG. 3 is a flowchart illustrating an example of a substrate processing method.

FIG. 4 is a diagram illustrating an example of a cross-sectional structure of a substrate in a step ST1.

FIG. 5 is a diagram illustrating an example of a cross-sectional structure of the substrate in a step ST2.

FIG. 6 is a diagram illustrating an example of a cross-sectional structure of the substrate in a step ST3.

FIG. 7 is a diagram illustrating an example of a cross-sectional structure of the substrate in a step ST4.

### DESCRIPTION OF EMBODIMENTS

Hereinafter, each embodiment according to the present disclosure will be described.

In one exemplary embodiment, there is provided a substrate processing method including: (a) providing a substrate including an etching target film having a recess on a substrate support in a chamber; (b) exposing the substrate to a first processing gas containing a first halogen and hydrogen to form a first layer on a surface of the recess, the first layer including at least one of a halogenated surface and a surface on which hydrogen halide is adsorbed; and (c) exposing the substrate to a plasma generated from a second processing gas containing a second halogen and a Group 14 element to form a second layer containing the second halogen and the Group 14 element on the surface of the recess.

According to one exemplary embodiment of the present disclosure, it is possible to provide a technique for controlling film formation performed on a surface of a recess of an etching target film.

In one exemplary embodiment, the surface of the recess includes a first region and a second region above the first region, and a thickness of the second layer formed in the first region is larger than a thickness of the second layer formed in the second region.

In one exemplary embodiment, the first region includes a surface of a bottom portion of the recess, and the second region includes a surface of a side wall of the recess.

In one exemplary embodiment, in the (b), a temperature of the substrate support or a temperature of the substrate is controlled to 250 °C or lower.

In one exemplary embodiment, in the (c), a bias signal is supplied to the substrate support.

In one exemplary embodiment, in the (b), a plasma is generated from the first processing gas, and a bias signal is not supplied to the substrate support.

In one exemplary embodiment, the substrate processing method further includes (d) etching the etching target film after the (c).

In one exemplary embodiment, a cycle including the (c) and the (d) is repeated.

In one exemplary embodiment, the first processing gas includes at least one selected from the group consisting of an HF gas, an HCl gas, an HBr gas, and an HI gas.

In one exemplary embodiment, the second processing gas includes at least one selected from the group consisting of a CF-based gas, a CHF-based gas, a CBr-based gas, a CHBr-based gas, a CCl-based gas, a CHCl-based gas, a CI-based gas, a CHI-based gas, and a SiCl-based gas.

In one exemplary embodiment, the etching target film is a film including at least one selected from the group consisting of silicon, carbon, and a metal.

In one exemplary embodiment, in the (c), the substrate is exposed to the plasma having a high electron density of 10¹⁵/m³ or more.

In one exemplary embodiment, the etching target film has a plurality of the recesses having different width dimensions.

In one exemplary embodiment, the recess of the etching target film has a trench shape or a hole shape.

In one exemplary embodiment, there is provided a substrate processing apparatus including: a chamber; a substrate support placed within the chamber; a plasma generator; and a controller, in which the controller is configured to execute (a) control of providing a substrate including an etching target film having a recess on a substrate support in a chamber, (b) control of exposing the substrate to a first processing gas containing a first halogen and hydrogen to form a first layer on a surface of the recess, the first layer including at least one of a halogenated surface and a surface on which hydrogen halide is adsorbed, and (c) control of exposing the substrate to a plasma generated from a second processing gas containing a second halogen and a Group 14 element to form a second layer containing the second halogen and the Group 14 element on the surface of the recess.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Example of Plasma Processing System

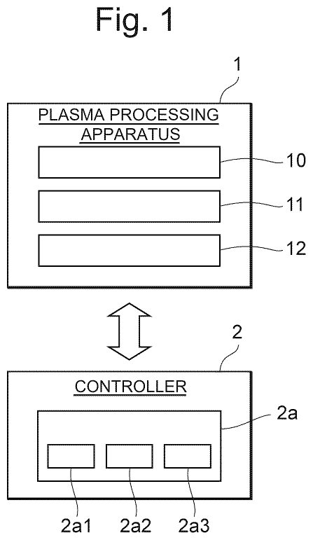

FIG. 1 is a diagram for describing a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20, described later, and the gas exhaust port is connected to an exhaust system 40 described later. The substrate support 11 is placed in the plasma processing space and has a substrate support surface for supporting a substrate.

The plasma generator 12 is configured to generate a plasma from at least one processing gas supplied into the plasma processing space. The plasma generated in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or the entirety of the controller 2 may be included in the plasma processing apparatus 1. The controller 2 may include, for example, a computer 2a. The computer 2a may include, for example, a processor (central processing unit (CPU)) 2a1, a storage 2a2, and a communication interface 2a3. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and is executed by the processor 2a1. The medium may be various storage media readable by the computer 2a or may be a communication line connected to the communication interface 2a3. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

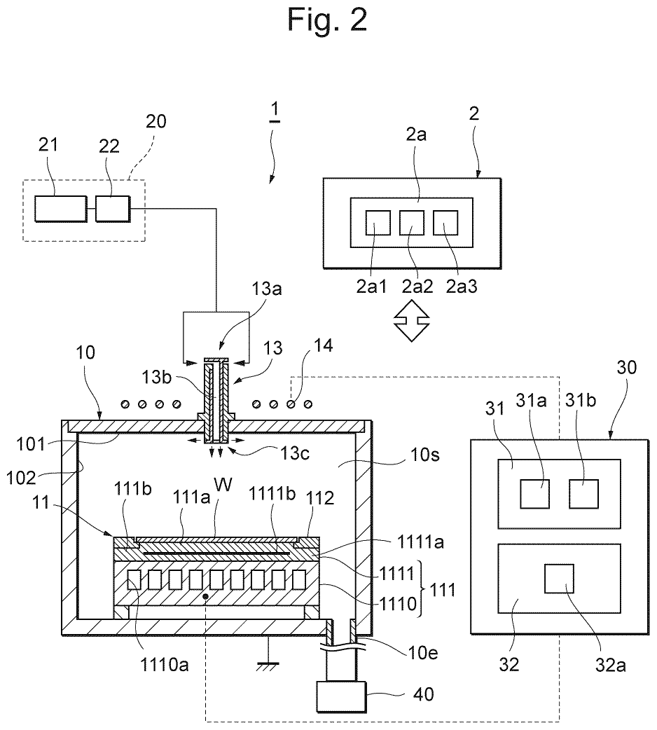

Hereinafter, a configuration example of an inductively coupled plasma processing apparatus as an example of the plasma processing apparatus 1 will be described. FIG. 2 is a diagram for describing a configuration example of an inductively coupled plasma processing apparatus. The inductively coupled plasma processing apparatus 1 includes the plasma processing chamber 10, the gas supply 20, a power supply 30, and the exhaust system 40. The plasma processing chamber 10 includes a dielectric window 101. In addition, the plasma processing apparatus 1 includes the substrate support 11, a gas introduction unit, and an antenna 14. The substrate support 11 is placed in the plasma processing chamber 10. The antenna 14 is placed on the plasma processing chamber 10 or above the plasma processing chamber 10 (that is, on the dielectric window 101 or above the dielectric window 101). The plasma processing chamber 10 has a plasma processing space 10s defined by the dielectric window 101, a side wall 102 of the plasma processing chamber 10, and the substrate support 11. The plasma processing chamber 10 is grounded.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is placed on the center region 111a of the main body 111, and the ring assembly 112 is placed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a bias electrode. The electrostatic chuck 1111 is placed on the base 1110. The electrostatic chuck 1111 includes a ceramic member 1111a and an electrostatic electrode 1111b placed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be placed on the annular electrostatic chuck or the annular insulating member, or may be placed on both the electrostatic chuck 1111 and the annular insulating member. In addition, an RF or DC electrode may be placed in the ceramic member 1111a, and in this case, the RF or DC electrode functions as a bias electrode. Both the conductive member of the base 1110 and the RF or DC electrode may function as two bias electrodes.

The ring assembly 112 includes one or multiple annular members. In an embodiment, the one or multiple annular members include one or multiple edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and the one or multiple heaters are placed in the ceramic member 1111a of the electrostatic chuck 1111. Further, the substrate support 11 may include a heat transfer gas supply configured to supply the heat transfer gas to a gap between a back surface of the substrate W and the center region 111a.

The gas introduction unit is configured to introduce at least one processing gas from the gas supply 20 into the plasma processing space 10s. In an embodiment, the gas introduction unit includes a center gas injector (CGI) 13. The center gas injector 13 is placed above the substrate support 11 and is attached to a center opening portion formed in the dielectric window 101. The center gas injector 13 has at least one gas supply port 13a, at least one gas flow passage 13b, and at least one gas introduction port 13c. The processing gas supplied to the gas supply port 13a passes through the gas flow passage 13b and is introduced into the plasma processing space 10s from the gas introduction port 13c. The gas introduction unit may include one or multiple side gas injectors (SGI) attached to one or multiple opening portions formed in the side wall 102, in addition to or instead of the center gas injector 13.

The gas supply 20 may include at least one gas source 21 and at least one flow rate controller 22. In an embodiment, the gas supply 20 is configured to supply at least one processing gas to the gas introduction unit from the gas source 21 corresponding to each processing gas via the flow rate controller 22 corresponding to each processing gas. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) such as a source RF signal and a bias RF signal to at least one bias electrode and the antenna 14. As a result, the plasma is generated from at least one processing gas supplied to the plasma processing space 10s. Therefore, the RF power supply 31 may function as at least a part of the plasma generator 12. In addition, by supplying the bias RF signal to at least one bias electrode, a bias potential is generated on the substrate W, and ions in the generated plasma can be attracted to the substrate W.

In an embodiment, the RF power supply 31 includes a first RF generator 31a and a second RF generator 31b. The first RF generator 31a is coupled to the antenna 14 via at least one impedance matching circuit, and is configured to generate a source RF signal (source RF power) for plasma generation. In an embodiment, the source RF signal has a frequency in the range of 10 MHz to 150 MHz. In an embodiment, the first RF generator 31a may be configured to generate multiple source RF signals having different frequencies. The generated one or multiple source RF signals are supplied to the antenna 14.

The second RF generator 31b is coupled to at least one bias electrode via at least one impedance matching circuit, and is configured to generate a bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in the range of 100 kHz to 60 MHz. In an embodiment, the second RF generator 31b may be configured to generate multiple bias RF signals having different frequencies. The generated one or multiple bias RF signals are supplied to at least one bias electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a bias DC generator 32a. In an embodiment, the bias DC generator 32a is connected to at least one bias electrode, and is configured to generate a bias DC signal. The generated bias DC signal is applied to at least one bias electrode.

In various embodiments, the bias DC signal may be pulsed. In this case, a sequence of voltage pulses based on the DC is applied to at least one bias electrode. The voltage pulse may have a pulse waveform having a rectangular shape, a trapezoidal shape, a triangular shape, or a combination thereof. In an embodiment, a waveform generator for generating a sequence of voltage pulses from the DC signal is connected between the bias DC generator 32a and at least one bias electrode. Therefore, the bias DC generator 32a and the waveform generator constitute a voltage pulse generator. The voltage pulse may have a positive polarity or a negative polarity. In addition, the sequence of voltage pulses may include one or multiple positive voltage pulses and one or multiple negative voltage pulses in one cycle. The bias DC generator 32a may be provided in addition to the RF power supply 31, or may be provided instead of the second RF generator 31b.

The antenna 14 includes one or multiple coils. In an embodiment, the antenna 14 may include an outer coil and an inner coil placed coaxially. In this case, the RF power supply 31 may be connected to both the outer coil and the inner coil, or may be connected to any one of the outer coil and the inner coil. In the former case, the same RF generator may be connected to both the outer coil and the inner coil, or separate RF generators may be connected to the outer coil and the inner coil, respectively.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### Example of Substrate Processing Method

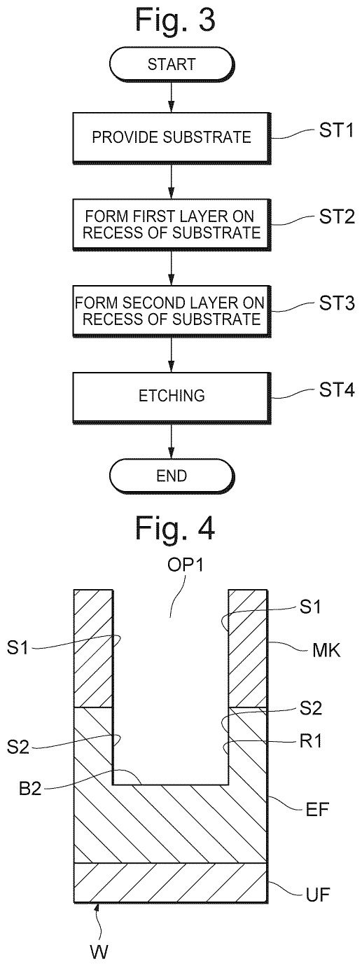

FIG. 3 is a flowchart illustrating an example of a substrate processing method (hereinafter, also referred to as “the present processing method”) according to one exemplary embodiment. As illustrated in FIG. 3, in an embodiment, the present processing method includes a step ST1 of providing a substrate, a step ST2 of forming a first layer in a recess of the substrate, a step ST3 of forming a second layer in the recess of the substrate, and a step ST4 of etching. The processing in each step may be executed by the plasma processing system illustrated in FIG. 2. A case where the controller 2 controls each unit of the plasma processing apparatus 1 to execute the present processing method on the substrate W will be described below as an example.

### Step ST1: Providing of Substrate)

In the step ST1, as illustrated in FIG. 2, the substrate W is provided in the plasma processing chamber 10 (hereinafter, also referred to as “the chamber 10”). In an embodiment, the substrate W is carried into the chamber 10 by a transfer arm, placed on the substrate support 11 by a lifter, and adsorptively held on the substrate support 11.

FIG. 4 is a diagram illustrating an example of a cross-sectional structure of the substrate W. In the substrate W, an etching target film EF and a mask MK are stacked in this order from below on an underlying film UF. The substrate W may be used for manufacturing a semiconductor device. The semiconductor device includes, for example, a memory device such as a DRAM or a 3D-NAND flash memory, and a logic device.

The mask MK may be a film that functions as a mask in the etching of the etching target film EF. The mask MK may have a side wall S1 that defines at least one opening OP1 on the etching target film EF. That is, the mask MK may have an opening OP1. The opening OP1 is a space on the recess R1 of the etching target film EF, and may be surrounded by the side wall S1 of the mask MK.

The opening OP1 may have any shape in plan view of the substrate W, that is, when the substrate W is viewed in a direction from top to bottom in FIG. 4. The shape may be, for example, a circle, an ellipse, a rectangle, a line, or a shape in which one or more of these are combined. The mask MK may have multiple side walls S1, and the multiple side walls S1 may define multiple openings OP1. The multiple openings OP1 may each have a linear shape and may be arranged at regular intervals or different intervals to form a line-and-space pattern. In addition, the multiple openings OP1 may each have a hole shape and may form an array pattern.

The mask MK may be a film containing at least one selected from the group consisting of silicon, carbon, and a metal. The silicon-containing film may be a silicon oxide film, a silicon nitride film, a silicon carbonitride film, a polycrystalline silicon film, or a carbon-containing silicon film. The silicon-containing film may be doped with an element such as phosphorus, boron, or nitrogen. The carbon-containing film may be a spin-on carbon (SOC) film, an amorphous carbon (ACL) film, a photoresist film, a tungsten carbide film, or a boron carbide film. The metal-containing film may be a film containing at least one metal selected from the group consisting of tungsten, molybdenum, ruthenium, titanium, and aluminum. The mask MK may be a single-layer mask consisting of one layer or a multi-layer mask consisting of two or more layers.

The etching target film EF may have at least one recess R1. The recess R1 may be placed to correspond to the opening OP1 of the mask MK. The recess R1 may have a side wall S2 and a bottom portion B2. The etching target film EF may have multiple recesses R1 having different width dimensions. The multiple recesses R1 may have a relatively wide width dimension and a relatively narrow width dimension. The recess R1 may have a trench shape or a hole shape.

The etching target film EF may be a film containing at least one selected from the group consisting of silicon, carbon, and a metal. The silicon-containing film may be a silicon oxide film, a silicon nitride film, a silicon carbonitride film, a polycrystalline silicon film, or a carbon-containing silicon film. The silicon-containing film may be doped with an element such as phosphorus, boron, or nitrogen. The carbon-containing film may be a spin-on carbon (SOC) film, an amorphous carbon (ACL) film, a photoresist film, a tungsten carbide film, or a boron carbide film. The metal-containing film may be a film containing at least one metal selected from the group consisting of tungsten, molybdenum, ruthenium, titanium, and aluminum.

The underlying film UF may be a silicon wafer, an organic film, a dielectric film, a metal film, a semiconductor film, or the like formed on the silicon wafer. The underlying film UF may be configured by stacking multiple films.

Each film constituting the substrate W may be formed by any method, respectively. The underlying film UF, the etching target film EF, and the mask MK may be formed by a CVD method, an ALD method, a PVD method, a spin coating method, or the like. The opening OP1 of the mask MK and the recess R1 of the etching target film EF may be formed by etching. The opening OP1 of the mask MK and the recess R1 of the etching target film EF may be formed by a lithography method. Each film may be a flat film or a film having unevenness. In addition, the substrate W may further have another film under the underlying film UF.

At least a part of a process of forming the underlying film UF, the etching target film EF, and the mask MK of the substrate W may be performed in the chamber 10 as a part of the step ST1. For example, the opening OP1 of the mask MK and/or the recess R1 of the etching target film EF may be formed by etching in the step ST1. In this case, the etching of the mask MK and/or the etching target film EF in the step ST1 and the steps ST2, ST3, and ST4 described later may be continuously executed in the chamber 10. In an embodiment, after all or a part of the films of the substrate W are formed by an apparatus or a chamber outside the plasma processing apparatus 1, the substrate W may be provided in the chamber 10.

In an embodiment, after the substrate W is provided on the substrate support 11, the temperature of the substrate support 11 or the substrate W is controlled to a given temperature by the temperature-controlled module. The control of the temperature of the substrate support 11 or the substrate W to the given temperature may include setting the temperature of the heat transfer fluid flowing through the flow passage 1110a or the heater temperature to the given temperature or to a temperature different from the given temperature. The given temperature may be, for example, 50 °C or lower and −50 °C or higher. The given temperature may be a room temperature (for example, 25 °C) or lower and 0 °C or lower. The timing at which the temperature of the substrate support 11 or the substrate W starts to be controlled to the given temperature may be before or after the substrate W is placed on the substrate support 11, or may be at the same time. The temperature of the substrate support 11 or the substrate W may be changed in each of the steps ST1 to ST4.

### Step ST2: Formation of First Layer

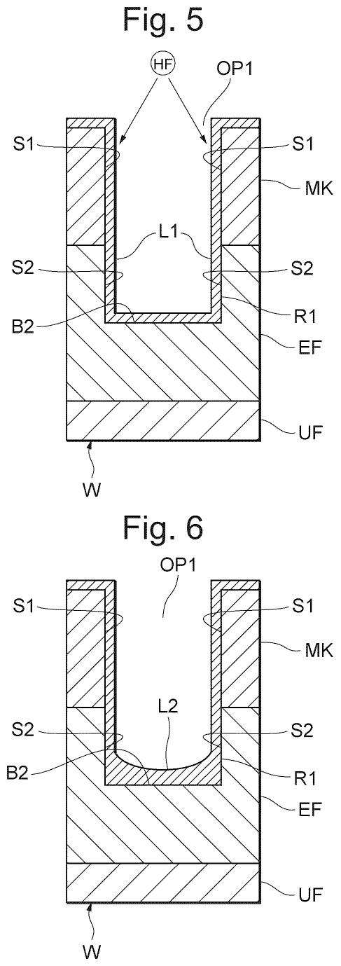

FIG. 5 is a diagram for describing an example of a cross-sectional structure of the substrate W in which the first layer L1 is formed on the surface of the recess R1 of the etching target film EF in the step ST2. In an embodiment, in the step ST2, the substrate W is exposed to the first processing gas to form the first layer L1 on the surface of the recess R1.

In an embodiment, in the step ST2, the first processing gas is supplied into the chamber 10 from the center gas injector 13 illustrated in FIG. 2. The temperature of the substrate support 11 or the substrate W may be controlled to a first temperature. The first temperature may be in a range of −70 °C or higher and 250 °C or lower. The first temperature may be 10 °C or lower or 0 °C or lower. The pressure in the chamber 10 may be adjusted to a first pressure. The first pressure may be in a range of 1 mTorr or higher and 1000 mTorr or lower, or in a range of 1 mTorr or higher and 100 mTorr or lower.

The first processing gas may be a gas containing a first halogen and hydrogen. The first halogen may be any of F, Cl, Br, and I. The first processing gas may contain hydrogen halide. The first processing gas may contain, as the hydrogen halide, at least one selected from the group consisting of an HF gas, an HCl gas, an HBr gas, and an HI gas. The first processing gas may be a gas containing a single gas of the first halogen and a single gas of hydrogen. The first processing gas may further contain an inert gas. The inert gas may be, for example, noble gas such as Ar gas, He gas, and Kr gas, or N₂ gas.

The substrate W in the chamber 10 is exposed to the first processing gas, and the first layer L1 is formed on the surface of the recess R1 as illustrated in FIG. 5. The first layer L1 is formed by halogenating the surface of the recess R1 and/or by adsorbing the hydrogen halide on the surface of the recess R1. The first layer L1 may include at least one of a halogenated surface and a surface on which the hydrogen halide is adsorbed. The first layer L1 may suppress the chemisorption of the dissociated neutral species in the plasma and the generation of the polymer thereof.

In the step ST2, the first processing gas exposed to the substrate W may not be in a plasma state. That is, the plasma may not be generated from the first processing gas supplied into the chamber 10. On the other hand, in the step ST2, the first processing gas exposed to the substrate W may be in the plasma state. That is, in the step ST2, the plasma may be generated from the first processing gas supplied into the chamber 10. In this case, the source RF signal is supplied from the first RF generator 31a to the antenna 14. As a result, an RF electric field is generated between the antenna 14 and the substrate support 11, and the plasma is generated from the processing gas in the plasma processing space 10s. At this time, the bias signal may not be supplied to the substrate support 11.

### Step ST3: Formation of Second Layer

FIG. 6 is a diagram for describing an example of a cross-sectional structure of the substrate W in which the second layer L2 is formed on the surface of the recess R1 of the etching target film EF in the step ST3. In an embodiment, in the step ST3, the substrate W is exposed to the plasma generated from the second processing gas, and the second layer L2 is formed on the surface of the recess R1.

In an embodiment, in the step ST3, the second processing gas is supplied into the chamber 10 from the center gas injector 13 illustrated in FIG. 2. The temperature of the substrate support 11 or the substrate W may be controlled to a second temperature. The second temperature may be in a range of 250 °C or lower and −70 °C or higher, or in a range of 80 °C or lower and 0 °C or higher. The second temperature may be higher than the first temperature. The pressure in the chamber 10 may be adjusted to a second pressure. The second pressure may be in a range of 1 mTorr or higher and 10000 mTorr or lower, or in a range of 50 mTorr or higher and 500 mTorr or lower. The second pressure may be higher than the first pressure.

The second processing gas may be a gas containing a second halogen and a Group 14 element. The second halogen may be any of F, Cl, Br, and I. The second halogen contained in the second processing gas may be the same as or different from the first halogen contained in the first processing gas. The Group 14 element may be any of C, Si, Ge, and Sn. The second processing gas may include at least one selected from the group consisting of a CF-based gas, a CHF-based gas, a CBr-based gas, a CHBr-based gas, a CCl-based gas, a CHCl-based gas, a Cl-based gas, a CHI-based gas, and a SiCl-based gas. CF-based gases (fluorocarbon gases) may include at least one selected from the group consisting of CF₄ gas, C₂F₂ gas, C₂F₄ gas, C₃F₆ gas, C₃F₈ gas, C₄F₆ gas, C₄F₈ gas, and C₅F₈ gas. The CHF-based (hydrofluorocarbon gas) may include at least one selected from CH₂F₂ gas, CH₃F gas, and CHF₃ gas. The CCl-based gas may include a CCl₄ gas. The CHCl-based gas may include at least one selected from CHCl₃ gas, CH₂Cl₂ gas, and CH₃Cl gas. The CI-based gas may include a CI₄ gas. CHI-based gases may include at least one selected from CHI₃ gas, CH₂I₂ gas, and CH₃I gas. The CBr-based gas may include a CBr₄ gas. CHBr-based gases may include at least one selected from CHBr₃ gas, CH₂Br₂ gas, and CH₃Br gas. The gas including C may include any of Si, Ge, or Sn instead of C. The second processing gas may include a gas represented by Xn-Hm-Yl (X=C, Si, Ge, or Sn, Y=F, Cl, Br, or I, and n, m, and l are each an integer of 0 or more). The second processing gas may further include an inert gas. The inert gas may be a noble gas such as Ar gas, He gas, or Kr gas, or N₂ gas.

In an embodiment, the plasma is generated from the second processing gas supplied into the chamber 10. In this case, the source RF signal is supplied from the first RF generator 31a to the antenna 14, and thus an RF electric field is generated between the antenna 14 and the substrate support 11, and the plasma is generated from the processing gas in the plasma processing space 10s. The source RF signal may have a power of 1 kW or more. The source RF signal may have a power of 1 kW or more and 10 kW or less. The plasma may have a high electron density of 10¹⁵/m³ or more, or may have a high electron density of 10¹⁷/m³ or more.

The first layer L1 is modified by ions or dissociated neutral species in the plasma, and the second layer L2 is formed on the surface of the recess R1 as illustrated in FIG. 6. The second layer L2 may be a protective film including a second halogen and a Group 14 element.

During the plasma generation, the bias signal may be supplied to the substrate support 11. The bias signal may be the bias RF signal supplied from the RF power supply 31 or the bias DC signal supplied from the DC power supply 32. In this case, the bias potential is generated between the plasma and the substrate W. The ions or dissociated neutral species in the plasma are attracted to the substrate W and are supplied into the recess R1.

Ions of atoms and molecules containing Group 14 elements, as well as dissociated neutral species, in the plasma are supplied to the recess R1 in a state where chemisorption and generation of the polymerization species are suppressed by the hydrogen halide in the first layer L1. Many of the ions in the plasma that are not consumed at the side wall S2 of the recess R1 may reach the bottom portion B2 of the recess R1 and be deposited.

For example, the second layer L2 thicker than the side wall S2 is formed on the bottom portion B2 of the recess R1.

### Step ST4: Etching

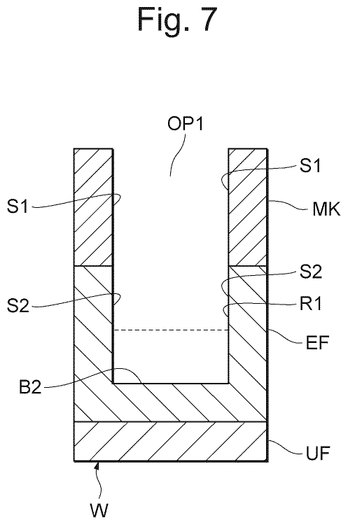

FIG. 7 is a diagram for describing an example of a cross-sectional structure of the substrate W in which the recess R1 of the etching target film EF is etched in the step ST4. In an embodiment, in the step ST4, the recess R1 of the etching target film EF is etched. As a result, the etching of the bottom portion B2 of the recess R1 proceeds in the depth direction, and a deeper recess R1 is formed in the etching target film EF. Furthermore, an opening may be formed in the etching target film EF, and the underlying film UF may be exposed at the opening.

In an embodiment, in the step ST4, etching gas is supplied into the chamber 10 from the center gas injector 13 illustrated in FIG. 2. The etching gas may include a gas including carbon and fluorine. The CF-based gas (fluorocarbon gas) may be at least one selected from the group consisting of C₄F₆ gas, C₄F₈ gas, C₃F₈ gas, CF₄ gas, C₂F₂ gas, C₂F₄ gas, C₃F₆ gas, and C₅F₈ gas. CHF-based gases (hydrofluorocarbon gases) may be at least one selected from the group consisting of CHF₃ gas, CH₂F₂ gas, CH₃F gas, C₃H₂F₄ gas, C₄H₂F₆ gas, C₂HF₅ gas, C₂H₂F₄ gas, C₂H₃F₃ gas, C₂H₄F₂ gas, C₃HF₇ gas, C₃H₂F₂ gas, C₃H₂F₆ gas, C₃H₃F₅ gas, C₄H₅F₅ gas, C₄H₂F₈ gas, C₅H₂F₆ gas, C₅H₂F₁₀ gas, and C₅H₃F₇ gas.

The plasma may be generated from the etching gas supplied into the chamber 10. In this case, the source RF signal is supplied to the antenna 14, and thus, an RF electric field is generated between the antenna 14 and the substrate support 11, and the plasma is generated from the processing gas in the plasma processing space 10s. In this case, the bias signal may be supplied to the substrate support 11. The bias signal may be the bias RF signal supplied from the RF power supply 31 or the bias DC signal supplied from the DC power supply 32. In this case, a bias potential is generated between the plasma and the substrate W. The active species such as ions and radicals in the plasma are attracted to the substrate W, and the bottom portion B2 of the recess R1 of the etching target film EF is etched in the depth direction by the active species.

The substrate W in which the step ST4 is completed may be carried out from the chamber 10 to the outside. In an embodiment, the substrate W may be carried out of the chamber 10 from the substrate support 11 by a lifter and a transfer arm.

The step ST2 and the step ST3 may be performed as separate steps, and may be continuously performed in an example. In addition, the step ST2 and the step ST3 may be performed at the same time.

In the present processing method, a cycle including the step ST3 and the step ST4 may be repeated a predetermined number of times. Further, in the present processing method, a cycle including the step ST2, the step ST3, and the step ST4 may be repeated a predetermined number of times.

According to the present exemplary embodiment, the substrate processing method includes (a) a step (ST1 step) of providing the substrate W including the etching target film EF on the substrate support 11 in the chamber 10, (b) a step (ST2 step) of exposing the substrate W to the first processing gas containing the first halogen and hydrogen to form the first layer L1 on the surface of the recess R1, and (c) a step (ST3 step) of exposing the substrate W to the plasma generated from the second processing gas containing the second halogen and the Group 14 element to form the second layer L2 containing the second halogen and the Group 14 element on a surface of the recess R1. In the ST2 step, the first layer L1 includes a halogenated surface and/or a surface with adsorbed hydrogen halide.

By forming the first layer L1 including the halogenated surface and/or the surface with adsorbed hydrogen halide on the surface of the recess R1 of the substrate W, it is possible to suppress the ions of the plasma and the dissociated neutral species from being chemically attached to the upper portion (for example, the side wall) of the recess R1 with a high probability. Therefore, the ions of the plasma or the dissociated neutral species are supplied to the bottom portion B2 of the recess R1, and the film formation can be performed in the bottom portion B2. As a result, the film formation of the second layer L2 in the bottom portion B2 (film thickness of the protective film) is appropriately performed regardless of the width (width dimension) or depth of the bottom portion B2. That is, it is possible to reduce the dependence of the film thickness of the second layer L2 in the bottom portion B2 on the CD (line width) or the aspect ratio of the etching target film EF (CD (line width) dependence or aspect ratio dependence). Since the second layer L2 at a deep position of the recess R1 is secured, bowing can be suppressed. As a result, it is possible to control the film formation performed on the surface of the recess of the etching target film.

According to the present exemplary embodiment, in the ST2 step, the temperature of the substrate support 11 or the temperature of the substrate W is controlled to 50 °C or lower. As a result, the amount of hydrogen halide adsorbed on the surface of the recess R1 increases, and as a result, in the ST3 step, it is possible to suppress the dissociated neutral species of the plasma from being chemically attached to the side wall of the recess R1 with a high probability.

According to the present exemplary embodiment, in the ST3 step, since the bias signal is supplied to the substrate support 11, the anisotropic incidence of the dissociated species of the plasma is realized, and the film formation can be appropriately performed in the bottom portion B2 of the recess R1.

According to the present exemplary embodiment, in the ST2 step, the plasma is generated from the first processing gas, and the bias signal is not supplied to the substrate support 11. As a result, the amount of hydrogen halide adsorbed on the upper portion (side wall) of the recess R1 increases, and as a result, in the ST3 step, it is possible to suppress the dissociated neutral species of the plasma from being chemically attached to the side wall of the recess R1 with a high probability.

According to the present exemplary embodiment, in the ST3 step, the substrate W is exposed to the plasma with high electron density and high dissociation, so that the film formation can be appropriately performed in the bottom portion B2 of the recess R1.

In the above-described embodiments, the present processing method is not limited to the inductively coupled plasma processing apparatus, and may be performed by another type of the plasma processing apparatus, for example, a plasma processing apparatus that generates a capacitively coupled plasma, a plasma processing apparatus that generates an ECR plasma, a plasma processing apparatus that generates a helicon wave plasma, or a plasma processing apparatus that generates a surface wave plasma.

The present disclosure may include, for example, the following configurations.

### Aspect 1

A substrate processing method including:
(a) providing a substrate including an etching target film having a recess on a substrate support in a chamber;
(b) exposing the substrate to a first processing gas containing a first halogen and hydrogen to form a first layer on a surface of the recess, the first layer including at least one of a halogenated surface and a surface on which hydrogen halide is adsorbed; and
(c) exposing the substrate to a plasma generated from a second processing gas containing a second halogen and a Group 14 element to form a second layer containing the second halogen and the Group 14 element on the surface of the recess.

### Aspect 2

The substrate processing method according to Aspect 1, in which the surface of the recess includes a first region and a second region above the first region, and
a thickness of the second layer formed in the first region is larger than a thickness of the second layer formed in the second region.

### Aspect 3

The substrate processing method according to Aspect 2, in which the first region includes a surface of a bottom portion of the recess, and
the second region includes a surface of a side wall of the recess.

### Aspect 4

The substrate processing method according to any one of Aspects 1 to 3, in which in the (b), a temperature of the substrate support or a temperature of the substrate is controlled to 250 °C or lower.

### Aspect 5

The substrate processing method according to any one of Aspects 1 to 4, in which in the (c), a bias signal is supplied to the substrate support.

### Aspect 6

The substrate processing method according to any one of Aspects 1 to 5, in which in the (b), a plasma is generated from the first processing gas, and a bias signal is not supplied to the substrate support.

### Aspect 7

The substrate processing method according to any one of Aspects 1 to 6,further including: (d) etching the etching target film after the (c).

### Aspect 8

The substrate processing method according to Aspect 7, in which a cycle including the (c) and the (d) is repeated.

### Aspect 9

The substrate processing method according to any one of Aspects 1 to 8, in which the first processing gas includes at least one selected from the group consisting of an HF gas, an HCl gas, an HBr gas, and an HI gas.

### Aspect 10

The substrate processing method according to any one of Aspects 1 to 9, in which the second processing gas includes at least one selected from the group consisting of a CF-based gas, a CHF-based gas, a CBr-based gas, a CHBr-based gas, a CCl-based gas, a CHCl-based gas, a CI-based gas, a CHI-based gas, and a SiCl-based gas.

### Aspect 11

The substrate processing method according to any one of Aspects 1 to 10, in which the etching target film is a film including at least one selected from the group consisting of silicon, carbon, and a metal.

### Aspect 12

The substrate processing method according to any one of Aspects 1 to 11, in which in the (c), the substrate is exposed to the plasma having a high electron density of 10¹⁵/m³ or more.

### Aspect 13

The substrate processing method according to any one of Aspects 1 to 12, in which the etching target film has a plurality of the recesses having different width dimensions.

### Aspect 14

The substrate processing method according to any one of Aspects 1 to 13, in which the recess of the etching target film has a trench shape or a hole shape.

### Aspect 15

A substrate processing apparatus including: a chamber; a substrate support placed within the chamber; a plasma generator; and a controller, in which the controller is configured to execute
(a) control of providing a substrate including an etching target film having a recess on a substrate support in a chamber,
(b) control of exposing the substrate to a first processing gas containing a first halogen and hydrogen to form a first layer on a surface of the recess, the first layer including at least one of a halogenated surface and a surface on which hydrogen halide is adsorbed, and
(c) control of exposing the substrate to a plasma generated from a second processing gas containing a second halogen and a Group 14 element to form a second layer containing the second halogen and the Group 14 element on the surface of the recess.

In the above exemplary embodiments, the plasma processing apparatus and the plasma processing method can be variously modified without departing from the scope and spirit of the present disclosure. For example, some configuration elements in one embodiment can be added to another embodiment within the range of the ordinary creativity of those skilled in the art. In addition, some configuration elements in one embodiment can be replaced with corresponding configuration elements in another embodiment.

1. A substrate processing method comprising:
(a) providing a substrate including an etching target film having a recess, on a substrate support in a chamber;
(b) exposing the substrate to a first processing gas containing a first halogen and hydrogen to form a first layer on a surface of the recess, the first layer including at least one of a halogenated surface and a surface on which hydrogen halide is adsorbed; and
(c) exposing the substrate to a plasma generated from a second processing gas containing a second halogen and a Group 14 element to form a second layer containing the second halogen and the Group 14 element on the surface of the recess.

2. The substrate processing method according to claim 1, wherein the surface of the recess includes a first region and a second region above the first region, and
a thickness of the second layer formed in the first region is larger than a thickness of the second layer formed in the second region.

3. The substrate processing method according to claim 2, wherein the first region includes a surface of a bottom portion of the recess, and
the second region includes a surface of a side wall of the recess.

4. The substrate processing method according to claim 1, wherein the (b) includes controlling a temperature of the substrate support or a temperature of the substrate to 250 °C or lower.

5. The substrate processing method according to claim 1, wherein the (c) includes supplying a bias signal to the substrate support.

6. The substrate processing method according to claim 1, wherein the (b) includes generating a plasma from the first processing gas, and not supplying a bias signal to the substrate support.

7. The substrate processing method according to claim 1, further comprising: (d) etching the etching target film after the (c).

8. The substrate processing method according to claim 7, wherein a cycle including the (c) and the (d) is repeated.

9. The substrate processing method according to claim 1, wherein the first processing gas includes at least one selected from the group consisting of an HF gas, an HCl gas, an HBr gas, and an HI gas.

10. The substrate processing method according to claim 1, wherein the second processing gas includes at least one selected from the group consisting of a CF-based gas, a CHF-based gas, a CBr-based gas, a CHBr-based gas, a CCl-based gas, a CHCl-based gas, a CI-based gas, a CHI-based gas, and a SiCl-based gas.

11. The substrate processing method according to claim 1, wherein the etching target film is a film including at least one selected from the group consisting of silicon, carbon, and a metal.

12. The substrate processing method according to claim 1, wherein the (c) includes exposing the substrate to the plasma having an electron density of 10¹⁵/m³ or more.

13. The substrate processing method according to claim 1, wherein the etching target film has a plurality of the recesses having different width dimensions.

14. The substrate processing method according to claim 1, wherein the recess of the etching target film has a trench shape or a hole shape.

15. A substrate processing apparatus comprising:
a chamber;
a substrate support placed within the chamber;
a gas supply configured to supply a processing gas into the chamber;
a plasma generator configured to generate a plasma in the chamber; and
controller circuitry, configured to:
(a) control the substrate support to hold a substrate including an etching target film having a recess,
(b) control the gas supply to supply a first processing gas containing a first halogen and hydrogen into the chamber to expose the substrate to the first processing gas to form a first layer on a surface of the recess, the first layer including at least one of a halogenated surface and a surface on which hydrogen halide is adsorbed, and
(c) control the gas supply to supply a second processing gas containing a second halogen and a Group 14 element into the chamber and control the plasma generator to generate a plasma from the second processing gas to expose the substrate to the plasma and to form a second layer containing the second halogen and the Group 14 element on the surface of the recess.

16. The substrate processing apparatus according to claim 15, wherein the surface of the recess includes a first region and a second region above the first region, and a thickness of the second layer formed in the first region is larger than a thickness of the second layer formed in the second region.

17. The substrate processing apparatus according to claim 15, wherein the controller circuitry is further configured to (d) control the gas supply to supply an etching gas into the chamber and control the plasma generator to generate a plasma from the etching gas to etch the etching target film after the (c).

18. A non-transitory computer-readable storage medium storing computer-executable instructions that, when executed by controller circuitry of a substrate processing apparatus that includes a chamber, a substrate support placed within the chamber, a gas supply configured to supply a processing gas into the chamber, and a plasma generator configured to generate a plasma in the chamber, cause the controller circuitry to:
(a) control the substrate support to hold a substrate including an etching target film having a recess; (b) control the gas supply to supply a first processing gas containing a first halogen and hydrogen into the chamber to expose the substrate to the first processing gas to form a first layer on a surface of the recess, the first layer including at least one of a halogenated surface and a surface on which hydrogen halide is adsorbed; and (c) control the gas supply to supply a second processing gas containing a second halogen and a Group 14 element into the chamber and control the plasma generator to generate a plasma from the second processing gas to expose the substrate to the plasma to form a second layer containing the second halogen and the Group 14 element on the surface of the recess.

19. The non-transitory computer-readable storage medium according to claim 18, wherein the instructions, when executed by the controller circuitry, further cause the controller circuitry to (d) control the gas supply to supply an etching gas into the chamber and control the plasma generator to generate a plasma from the etching gas to etch the etching target film after the (c).

20. The non-transitory computer-readable storage medium according to claim 18, wherein the instructions, when executed by the controller circuitry, cause the controller circuitry to control, in the (b), a temperature of the substrate support or a temperature of the substrate to 250 °C or lower.
